(19) United States
(12) Patent Application Publication
(10) Pub. No.: US 2025/0364234 A1
(43) Pub. Date: Nov. 27, 2025

(54) ANOMALY DETECTION METHOD AND PLASMA PROCESSING DEVICE

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 19/286,582

(22) Filed: Jul. 31, 2025

Related U.S. Application Data
(63) Continuation of application No. PCT/JP2024/001918, filed on Jan. 23, 2024.

(30) Foreign Application Priority Data
Feb. 13, 2023 (JP) 2023-020135

(51) Int. Cl. H01J 37/32

(52) U.S. Cl. CPC H01J 37/32935; H01J 37/32082

(57) ABSTRACT

An anomaly detection method includes changing at least one processing condition of plasma processing in cycles. The plasma processing is performed in a chamber in a plasma processing device. The anomaly detection method further includes obtaining, in a series of the cycles being repeated and in which the at least one processing condition is changed, a value of at least one state of plasma in the chamber at each phase in each of the cycles in the series. The anomaly detection method further includes detecting an anomaly in the plasma by comparing the value of the at least one state at each phase in each of the cycles in the series with a reference value obtained based on values of the at least one state at corresponding phases in one or more preceding cycles in the series.

### CROSS-REFERENCE TO RELATED APPLICATIONS

This application is a continuation application of PCT Application No. PCT/JP2024/001918, filed on Jan. 23, 2024, which claims the benefit of priority from Japanese Patent Application No. 2023-020135, filed on Feb. 13, 2023. The entire contents of the above listed PCT and priority applications are incorporated herein by reference.

### BACKGROUND

### Field

Exemplary embodiments of the disclosure relate to an anomaly detection method and a plasma processing device.

### Description of the Related Art

A plasma processing device performs plasma processing of substrates. Japanese Unexamined Patent Application Publication No. 2004-14797 describes a plasma processing device that detects an anomaly in plasma processing based on the emission wavelength and the emission intensity of plasma.

### SUMMARY

An anomaly detection method according to one exemplary embodiment is provided. The anomaly detection method includes changing at least one processing condition of plasma processing in cycles. The plasma processing is performed in a chamber in a plasma processing device. The anomaly detection method further includes obtaining, in a series of the cycles being repeated and in which the at least one processing condition is changed, a value of at least one state of plasma in the chamber at each phase in each of the cycles in the series. The anomaly detection method further includes detecting an anomaly in the plasma by comparing the value of the at least one state at each phase in each of the cycles in the series with a reference value obtained based on values of the at least one state at corresponding phases in one or more preceding cycles in the series.

### BRIEF DESCRIPTION OF THE DRAWINGS

FIG. 1 is a diagram of a plasma processing system, illustrating an example structure.

FIG. 2 is a diagram of a capacitively coupled plasma processing device, illustrating an example structure.

FIG. 3 is a diagram of a plasma processing device according to one exemplary embodiment.

FIG. 4 is a flowchart of an anomaly detection method according to one exemplary embodiment.

FIG. 5 is an example timing chart for the anomaly detection method according to the exemplary embodiment.

FIG. 6 is another timing chart for the anomaly detection method according to the exemplary embodiment.

### DETAILED DESCRIPTION

Exemplary embodiments will now be described in detail with reference to the drawings. In the drawings, like reference numerals denote like or corresponding components.

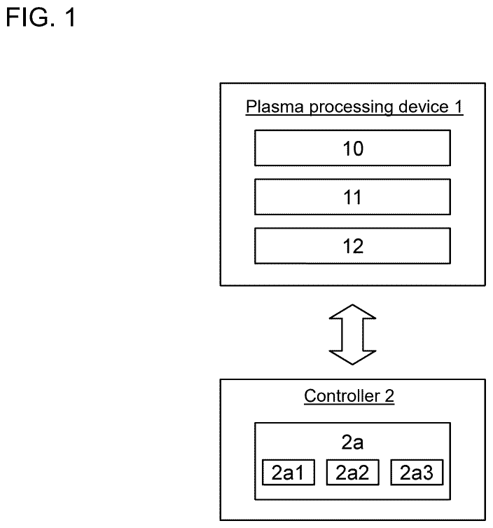

FIG. 1 is a diagram of a plasma processing system, illustrating an example structure. In one embodiment, the plasma processing system includes a plasma processing device 1 and a controller 2. The plasma processing system is an example of a substrate processing system. The plasma processing device 1 is an example of a substrate processing device. The plasma processing device 1 includes a plasma processing chamber 10, a substrate support 11, and a plasma generator 12. The plasma processing chamber 10 has a plasma processing space. The plasma processing chamber 10 has at least one gas inlet for supplying at least one process gas into the plasma processing space and at least one gas outlet for discharging the gas from the plasma processing space. The gas inlet connects to a gas supply 20 (described later). The gas outlet connects to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be capacitively coupled plasma (CCP), inductively coupled plasma (ICP), electron cyclotron resonance (ECR) plasma, helicon wave plasma (HWP), or surface wave plasma (SWP). Various plasma generators may be used, including an alternating current (AC) plasma generator and a direct current (DC) plasma generator. In one embodiment, an AC signal (AC power) used in the AC plasma generator has a frequency in a range of 100 kHz to 10 GHz. Thus, the AC signal includes a radio-frequency (RF) signal and a microwave signal. In one embodiment, the RF signal has a frequency in a range of 100 kHz to 150 MHz.

The controller 2 processes computer-executable instructions that cause the plasma processing device 1 to perform various steps described in one or more embodiments of the disclosure. The controller 2 may control the components of the plasma processing device 1 to perform the various steps described herein. In one embodiment, some or all of the components of the controller 2 may be included in the plasma processing device 1. The controller 2 may include a processor 2a1, a storage 2a2, and a communication interface 2a3. The controller 2 is implemented by, for example, a computer 2a. The processor 2al may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a, or a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing device 1 through a communication line such as a local area network (LAN).

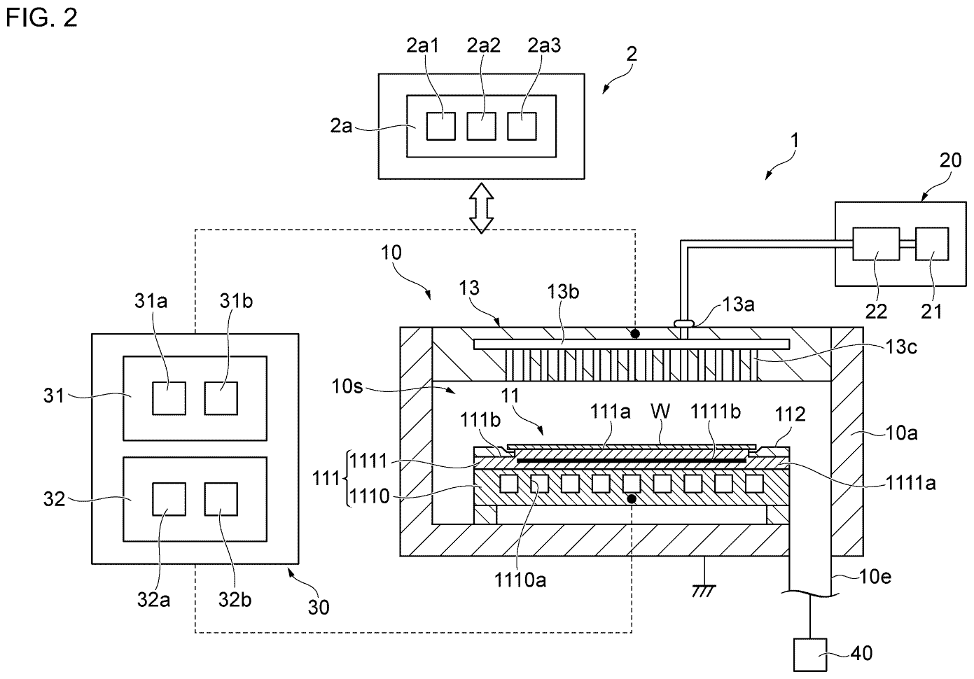

A capacitively coupled plasma processing device with an example structure will now be described as an example of the plasma processing device 1. FIG. 2 is a diagram of the capacitively coupled plasma processing device, illustrating an example structure.

The capacitively coupled plasma processing device 1 includes the plasma processing chamber 10, the gas supply 20, a power supply 30, and the exhaust system 40. The plasma processing device 1 also includes the substrate support 11 and a gas guide unit. The gas guide unit allows at least one process gas to be introduced into the plasma processing chamber 10. The gas guide unit includes a shower head 13. The substrate support 11 is located in the plasma processing chamber 10. The shower head 13 is located above the substrate support 11. In one embodiment, the shower head 13 defines at least a part of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from the housing of the plasma processing chamber 10.

The substrate support 11 includes a body 111 and a ring assembly 112. The body 111 includes a central area 111a for supporting a substrate W and an annular area 111b for supporting the ring assembly 112. A wafer is an example of the substrate W. The annular area 111b of the body 111 surrounds the central area 111a of the body 111 as viewed in plan. The substrate W is located on the central area 111a of the body 111. The ring assembly 112 is located on the annular area 111b of the body 111 to surround the substrate W on the central area 111a of the body 111. Thus, the central area 111a is also referred to as a substrate support surface for supporting the substrate W. The annular area 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may serve as a lower electrode. The ESC 1111 is located on the base 1110. The ESC 1111 includes a ceramic member 1111a and an electrostatic electrode 1111b inside the ceramic member 1111a. The ceramic member 1111a includes the central area 111a. In one embodiment, the ceramic member 1111a also includes the annular area 111b. The annular area 111b may be included in another member surrounding the ESC 1111, such as an annular ESC or an annular insulating member. In this case, the ring assembly 112 may be located on either the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, at least one RF/DC electrode serves as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may serve as multiple lower electrodes. The electrostatic electrode 1111b may also serve as a lower electrode. Thus, the substrate support 11 includes at least one lower electrode.

The ring assembly 112 includes one or more annular members. In one embodiment, one or more annular members include one or more edge rings and at least one cover ring. The edge rings are formed from a conductive material or an insulating material. The cover ring is formed from an insulating material.

The substrate support 11 may also include a temperature control module that adjusts the temperature of at least one of the ESC 1111, the ring assembly 112, or the substrate to be a target temperature. The temperature control module may include a heater, a heat transfer medium, a channel 1110a, or a combination of these. The channel 1110a carries a heat transfer fluid such as brine or gas. In one embodiment, the channel 1110a is defined in the base 1110, and one or more heaters are located in the ceramic member 1111a in the ESC 1111. The substrate support 11 may include a heat transfer gas supply to supply a heat transfer gas into a space between the back surface of the substrate W and the central area 111a.

The shower head 13 introduces at least one process gas from the gas supply 20 into the plasma processing space 10s. The shower head 13 includes at least one gas inlet 13a, at least one gas-diffusion compartment 13b, and multiple gas guides 13c. The process gas supplied to the gas inlet 13a passes through the gas-diffusion compartment 13b and is introduced into the plasma processing space 10s through the multiple gas guides 13c. The shower head 13 also includes at least one upper electrode. In addition to the shower head 13, the gas guide unit may include one or more side gas injectors (SGIs) installed in one or more openings in the side wall 10a.

The gas supply 20 may include at least one gas source 21 and at least one flow controller 22. In one embodiment, the gas supply 20 supplies at least one process gas from each gas source 21 to the shower head 13 through the corresponding flow controller 22. Each flow controller 22 may include, for example, a mass flow controller or a pressure-based flow controller. The gas supply 20 may further include at least one flow rate modulator that allows supply of at least one process gas at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This causes plasma to be generated from at least one process gas supplied into the plasma processing space 10s. The RF power supply 31 may thus at least partially serve as the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit and generates a source RF signal (source RF power) for plasma generation. In one embodiment, the source RF signal has a frequency in a range of 10 to 150 MHz. In one embodiment, the first RF generator 31a may generate multiple source RF signals with different frequencies. The generated one or more source RF signals are provided to at least one lower electrode or at least one upper electrode, or both.

The second RF generator 31b is coupled to at least one lower electrode through at least one impedance matching circuit and generates a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHZ. In one embodiment, the second RF generator 31b may generate multiple bias RF signals with different frequencies. The generated one or more bias RF signals are provided to at least one lower electrode. In various embodiments, at least one of the source RF signal or the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is coupled to at least one lower electrode and generates a first DC signal. The generated first DC signal is applied to at least one lower electrode. In one embodiment, the second DC generator 32b is coupled to at least one upper electrode and generates a second DC signal. The generated second DC signal is applied to at least one upper electrode.

In various embodiments, the first DC signal and the second DC signal may be pulsed. In this case, a sequence of voltage pulses is applied to at least one lower electrode or at least one upper electrode, or both. The voltage pulses may have a rectangular, trapezoidal, or triangular pulse waveform, or a combination of these pulse waveforms. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive or negative polarity. The sequence of voltage pulses may also include one or more positive voltage pulses and one or more negative voltage pulses within one cycle. The power supply 30 may include the first DC generator 32a and the second DC generator 32b in addition to the RF power supply 31. The first DC generator 32a may replace the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

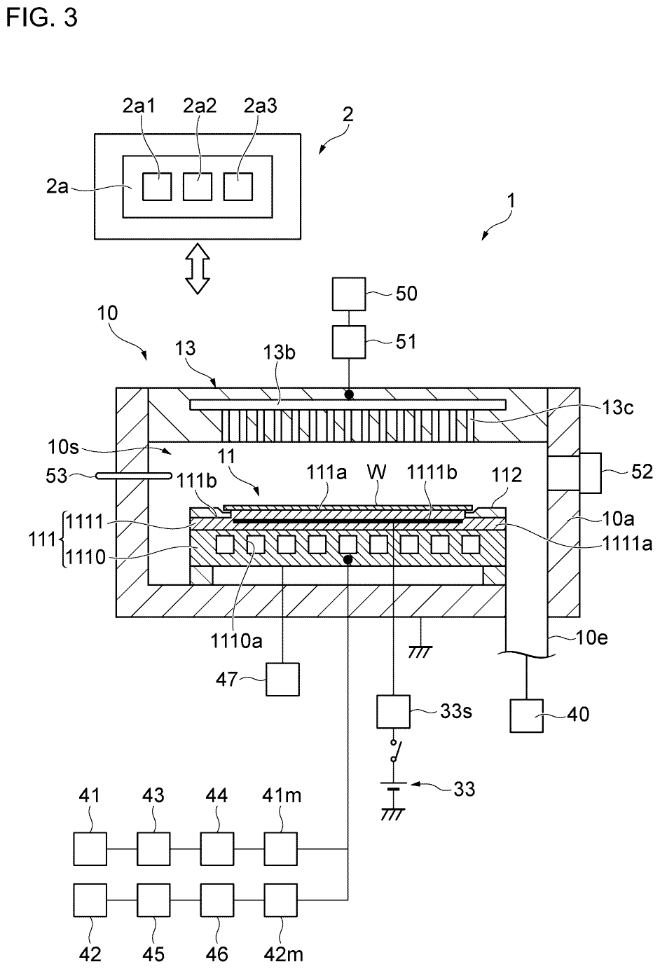

FIG. 3 will now be referred to. FIG. 3 is a diagram of the plasma processing device according to one exemplary embodiment. As shown in FIG. 3, the plasma processing device 1 further includes a DC power supply 33. The DC power supply 33 is coupled to the electrostatic electrode 1111b with a switch. A DC voltage is applied from the DC power supply 33 to the electrostatic electrode 1111b to generate an electrostatic attraction between the ESC 1111 and the substrate W. The electrostatic attraction causes the ESC 1111 to attract and hold the substrate W.

The plasma processing device 1 may further include a sensor 33s. The sensor 33s measures a clamping voltage value and a clamping current value of the ESC 1111. The clamping voltage is a voltage across the electrostatic electrode 1111b. The clamping current is a current flowing through the electrostatic electrode 1111b.

The plasma processing device 1 further includes an RF power supply 41. The RF power supply 41 is the first RF generator 31a described above. The RF power supply 41 generates a first RF signal, or specifically, a source RF power HF, to generate plasma in the chamber 10. The RF power supply 41 is coupled to the upper electrode or the lower electrode through an impedance matching circuit 41m.

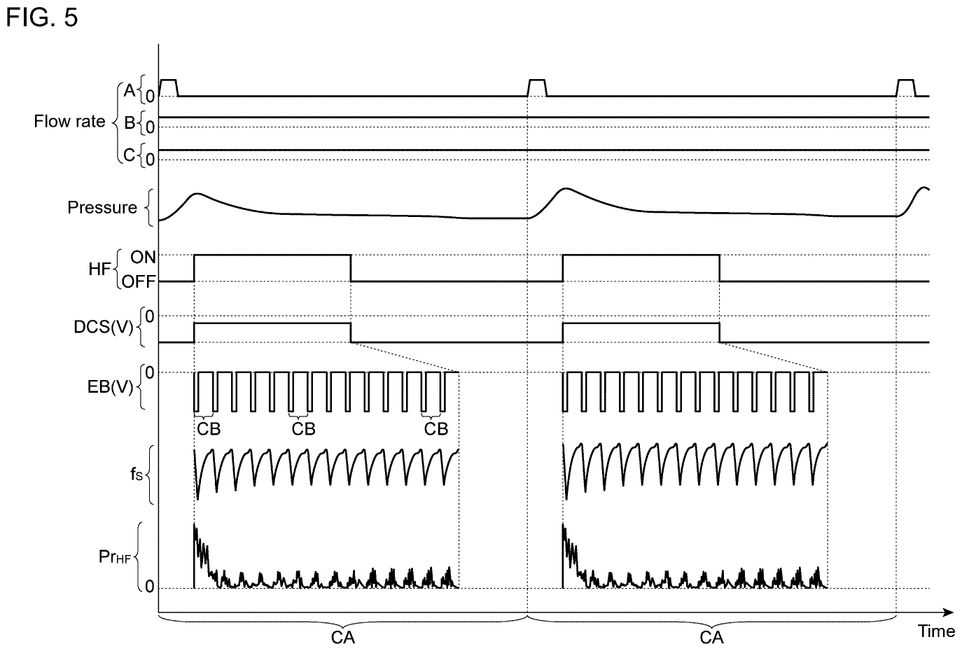

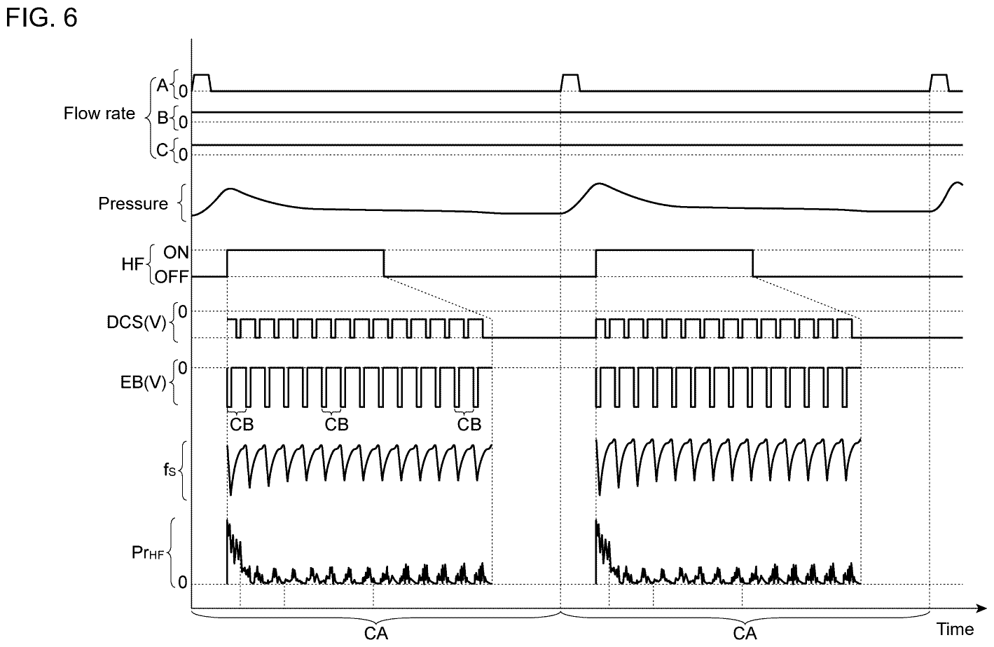

The plasma processing device 1 further includes a bias power supply 42. The bias power supply 42 provides an electrical bias EB to the lower electrode to draw ions toward the substrate W. The electrical bias EB has waveform cycles CB (refer to FIG. 5 or FIG. 6) and is provided cyclically at a time interval of the waveform cycle CB. The waveform cycle CB has a duration being the inverse of the frequency of the electrical bias EB, or specifically, the inverse of a bias frequency. The bias frequency is in a range of 100 kHz to 60 MHz inclusive.

The bias power supply 42 is the second RF generator 31b described above or includes the first DC generator 32a and the waveform generator described above. The bias power supply 42 being the second RF generator 31b provides a second RF signal, or specifically, bias RF power with the bias frequency, to the lower electrode through an impedance matching circuit 42m.

The bias power supply 42 including the first DC generator 32a and the waveform generator cyclically applies the pulsed first DC signal, or specifically, a voltage pulse (refer to FIGS. 5 and 6), to the lower electrode at a time interval of the waveform cycle CB. For the bias power supply 42 including the first DC generator 32a and the waveform generator, the plasma processing device 1 includes no impedance matching circuit 42m.

The RF power supply 41 may change the frequency of the source RF power HF, or specifically, a source frequency f_{S}, in the waveform cycle CB (FIGS. 5 and 6). The source frequency f_{S} in each phase in the waveform cycle CB is adjusted to reduce the degree of reflection of the source RF power HF from a load of the RF power supply 41.

The plasma processing device 1 may further include a sensor 43 and a sensor 44. The sensor 43 is a directional coupler that measures a power level Pf_{HF} of a traveling wave of the source RF power HF and the degree of reflection of the source RF power HF from the load. The degree of reflection of the source RF power HF may be a power level Pr_{HF} of a reflected wave of the source RF power HF or a reflectance of the source RF power HF (specifically, Pr_{HF}/Pf_{HF}). The sensor 44 is a VI sensor that measures at least one of the voltage value on a feed line for the source RF power HF, the current value on the feed line, or the phase difference between the voltage and the current on the feed line.

The plasma processing device 1 may further include a sensor 45 and a sensor 46. The sensor 45 is a directional coupler that measures a power level Pf_{EB} of a traveling wave of the electrical bias EB and the degree of reflection of the electrical bias EB from the load. The degree of reflection of the electrical bias EB may be a power level Pr_{EB} of a reflected wave of the electrical bias EB or a reflectance of the electrical bias EB (specifically, Pr_{EB}/Pf_{EB}). The sensor 46 is a VI sensor that measures the voltage value on a feed line for the electrical bias EB, the current value on the feed line, and the phase difference between the voltage and the current on the feed line.

The plasma processing device 1 may further include a sensor 47. The sensor 47 is a voltage sensor that measures the voltage value of the lower electrode or the ESC 1111.

The plasma processing device 1 may include a power supply 50. The power supply 50 is the second DC generator 32b described above or includes the second DC generator 32b and the waveform generator. The power supply 50 applies the second DC signal or the pulsed second DC signal, or specifically, a DC voltage or a pulsed DC voltage, to the upper electrode. The voltage applied from the power supply 50 to the upper electrode is hereafter referred to as a voltage DCS.

The plasma processing device 1 may further include a sensor 51. The sensor 51 is a VI sensor that measures the voltage value and the current value of the upper electrode.

The plasma processing device 1 may further include an optical emission spectrometer 52. The optical emission spectrometer 52 measures the emission spectrum of plasma in the chamber 10, or specifically, the emission intensity of light of at least one wavelength in the chamber 10.

The plasma processing device 1 may further include a probe 53. The probe 53 is any of, for example, a Langmuir probe or a plasma absorption probe, and measures the electron density in the chamber 10.

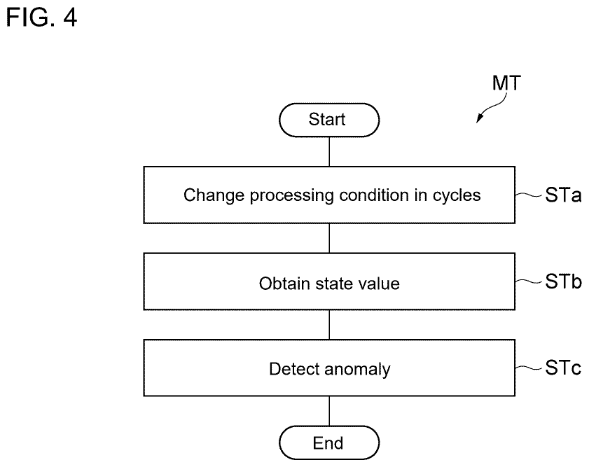

An anomaly detection method according to one exemplary embodiment will now be described with reference to FIG. 4. The control of the components of the plasma processing device 1 performed by the controller 2 and the processing performed by the controller 2 for the anomaly detection method will also be described. FIG. 4 is a flowchart of the anomaly detection method according to the exemplary embodiment.

FIGS. 5 and 6 will be referred to, in addition to FIG. 4. FIGS. 5 and 6 are timing charts each for the anomaly detection method according to the exemplary embodiment. In FIGS. 5 and 6, the flow rate indicates the flow rate of each of a gas A, a gas B, and a gas C supplied from the gas supply 20 into the chamber 10. The gas supplied from the gas supply 20 into the chamber 10 may include a single type of gas or multiple types of gases. In FIGS. 5 and 6, the pressure indicates the pressure in the chamber 10. In FIGS. 5 and 6, HF being ON indicates the source RF power HF being provided, and HF being OFF indicates the source RF power HF being stopped. In FIGS. 5 and 6, DCS (V) indicates the voltage level of the voltage DCS. In FIGS. 5 and 6, EB (V) indicates the voltage level of the electrical bias EB. In FIGS. 5 and 6, f_{S} indicates the frequency of the source RF power HF, or specifically, the source frequency f_{S}. In FIGS. 5 and 6, Pr_{HF} indicates the power level of the reflected wave of the source RF power HF from the load.

With the anomaly detection method shown in FIG. 4 (hereafter referred to as a method MT), the controller 2 controls the components of the plasma processing device 1. As shown in FIG. 4, the method MT includes steps STa to STc. In step STa, at least one processing condition for plasma processing performed in the chamber 10 is changed in cycles. At least one processing condition is changed in cycles at a time interval of the waveform cycle CA. The repeated cycles CA form a series CAS.

As shown in FIGS. 5 and 6, the cycle CA may be a cycle in which the condition of the gas supplied into the chamber 10 is changed. The condition of the gas supplied into the chamber 10 may include the flow rate of at least one gas supplied into the chamber 10 or the type of at least one gas supplied into the chamber 10, or both. In some embodiments, the cycle CA may be a cycle in which a pulse of the source RF power HF is provided to generate plasma in the chamber 10. The cycle CA may also be a cycle in which a pulse of the electrical bias EB is provided to the substrate support 11 in the chamber 10. In some embodiments, the cycle CA may be a cycle in which a pulse of the voltage DCS is provided cyclically.

As shown in FIGS. 5 and 6, the pulses of the source RF power HF, the voltage DCS, and the electrical bias EB may be synchronized with one another. In some embodiments, the pulse of the source RF power HF, the voltage DCS, or the electrical bias EB may have a different phase from or an inverted phase of the phase of another pulse of these pulses. As shown in FIG. 5, the pulse of the voltage DCS may be a single pulse generated in the cycle CA. In some embodiments, as shown in FIG. 6, the pulse of the voltage DCS may include a sequence of multiple pulses generated in the cycle CA.

In step STb, the controller 2 obtains a value of at least one state of the plasma in the chamber 10 at each phase in each cycle CA in the series CAS. Each phase in the cycle CA is indicated by a time elapsed from a start point of the cycle CA. In the example described below, a phase Pₙ indicates the phase in each cycle CA in the series CAS, and n is an index indicating a time elapsed from the start point of the cycle CA. The phases Pₙ in the multiple cycles CA in the series CAS correspond to one another.

The value of at least one state obtained in step STb may include a single type of state value or multiple types of state values. In the example described below, a state value Cₘ[Pₙ] indicates the state value at the phase Pₙ obtained in step STb, and m is an index indicating the type of the state value. When a single type of state value is obtained in step STb, m is 1. When M types of state values are obtained in step STb, m is a value of 1 to M.

At least one state value Cₘ[Pₙ] obtained in step STb includes at least one state value selected from the group consisting of multiple types of state values described below.
The voltage value on the feed line for the source RF power HF obtained by the sensor 44
The current value on the feed line for the source RF power HF obtained by the sensor 44
The phase difference between the voltage and the current on the feed line for the source RF power HF obtained by the sensor 44
The voltage value on the feed line for the electrical bias EB obtained by the sensor 46
The current value on the feed line for the electrical bias EB obtained by the sensor 46
The phase difference between the voltage and the current on the feed line for the electrical bias EB obtained by the sensor 46
The power level Pf_{HF} of the traveling wave of the source RF power HF obtained by the sensor 43
The degree of reflection of the source RF power HF obtained by the sensor 43 (e.g., Pr_{HF})
The power level of the traveling wave of the electrical bias EB obtained by the sensor 45
The degree of reflection of the electrical bias EB obtained by the sensor 45
The voltage value of the lower electrode or the ESC 1111 in the substrate support 11 obtained by the sensor 47
The clamping voltage value of the ESC 1111 obtained by the sensor 33s
The clamping current value of the ESC 1111 obtained by the sensor 33s
The emission intensity in the chamber 10 obtained by the optical emission spectrometer 52
The electron density in the chamber 10 obtained by the probe 53
The voltage value of the upper electrode obtained by the sensor 51
The current value of the upper electrode obtained by the sensor 51

In subsequent step STc, an anomaly in plasma generated in the chamber 10 is detected. Anomaly detection in Step STc is performed by the controller 2. More specifically, in step STc, the state value Cₘ[Pₙ] in each cycle CA in the series CAS is compared with a reference value Rₘ[Pₙ]. The reference value Rₘ[Pₙ] is for the state value Cₘ[Pₙ]. The reference value Rₘ[Pₙ] is obtained based on the state values Cₘ[Pₙ] at the corresponding phases Pₙ in one or more preceding cycles CA in the series CAS. In one embodiment, the reference value Rₘ[Pₙ] may be the average of the state values Cₘ[Pₙ] at the corresponding phases Pₙ in multiple preceding cycles in the series CAS. In the initial cycle CA in the series CAS, a past value or an empirically determined value may be used as the reference value Rₘ[Pₙ] to be compared with the state value Cₘ[Pₙ].

In step STc, the controller 2 may detect an anomaly based on the magnitude of an absolute value Dₘ[Pₙ] of the difference between the state value Cₘ[Pₙ] and the reference value Rₘ[Pₙ]. The value Dₘ[Pₙ] is an absolute value obtained by subtracting the reference value Rₘ[Pₙ] from the state value Cₘ[Pₙ].

In one embodiment, the controller 2 may provide an alert indicating an anomaly in the plasma processing device 1 when the absolute value Dₘ[Pₙ] is greater than a first threshold Th1ₘ[Pₙ]. The first threshold Th1ₘ[Pₙ] is compared with the absolute value Dₘ[Pₙ] to detect an anomaly based on the state value Cₘ[Pₙ]. The first threshold Th1ₘ[Pₙ] may be predetermined. In some embodiments, the first threshold Th1ₘ[Pₙ] may be Q₁ times a standard deviation of the state values Cₘ[Pₙ] in multiple preceding cycles CA in the series CAS. The value Q₁ is a positive value. The value Q₁ may be an integer. The value Q₁ may be 3. The alert may appear on the display in the plasma processing device 1 or may be generated as an alarm.

In one embodiment, the controller 2 may stop the operation of the plasma processing device 1 when the absolute value Dₘ[Pₙ] is greater than a second threshold Th2ₘ[Pₙ]. The second threshold Th2ₘ[Pₙ] is compared with the absolute value Dₘ[Pₙ] to detect an anomaly based on the state value Cₘ[Pₙ]. The second threshold Th2ₘ[Pₙ] is greater than the first threshold Th1ₘ[Pₙ]. The second threshold Th2ₘ[Pₙ] may be predetermined. In some embodiments, the second threshold Th2ₘ[Pₙ] may be Q₂ times the standard deviation of the state values Cₘ[Pₙ] in multiple preceding cycles CA in the series CAS. The value Q₂ is a positive value and is greater than Q₁. The value Q₂ may be an integer. The value Q₂ may be 4.

With the method MT and the plasma processing device 1 described above, the state value Cₘ[Pₙ] at the phase Pₙ in each cycle CA in the series CAS is compared with the reference value Rₘ[Pₙ] obtained based on the corresponding phases Pₙ in one or more preceding cycles CA. With the method MT and the plasma processing device 1, an anomaly in the state of plasma at the corresponding phases in multiple cycles CA in the series CAS may thus be detected. The method MT and the plasma processing device 1 thus allow detection of an anomaly in plasma processing for which processing conditions are changed in cycles.

The first threshold Th1ₘ[Pₙ] and the second threshold Th2ₘ[Pₙ] may be changed based on the order of the cycles CA in the series CAS or the phase Pₙ in each cycle CA, or both. Each of the first threshold Th1ₘ[Pₙ] and the second threshold Th2ₘ[Pₙ] may be determined based on the corresponding standard deviation obtained by the plasma processing device 1 or a controller in a host system for the plasma processing device 1 when the process is stable. The plasma processing device 1 or the controller in the host system for the plasma processing device 1 may obtain, for each of different processes, various numerical values (e.g., the standard deviation, the maximum value, and the minimum value of the state values Cₘ[Pₙ]) during the process. The controller may store these numerical values in a manner associated with information identifying the corresponding process. The controller may use, for anomaly analysis, the numerical values associated with the information identifying the process during the process.

Although various exemplary embodiments have been described above, the embodiments are not restrictive, and various additions, omissions, substitutions, and changes may be made. The components in the different exemplary embodiments may be combined to form another exemplary embodiment.

Various exemplary embodiments E1 to E16 included in the disclosure will now be described.

### E1

An anomaly detection method, comprising:
changing at least one processing condition of plasma processing in cycles, the plasma processing being performed in a chamber in a plasma processing device;
obtaining, in a series of the cycles being repeated and in which the at least one processing condition is changed, a value of at least one state of plasma in the chamber at each phase in each of the cycles in the series; and
detecting an anomaly in the plasma by comparing the value of the at least one state at each phase in each of the cycles in the series with a reference value obtained based on values of the at least one state at corresponding phases in one or more preceding cycles in the series.

### E2

The anomaly detection method according to E1, wherein
the cycles are
   cycles in which a pulse of a source radio-frequency power is provided to generate the plasma in the chamber,
   cycles in which a pulse of an electrical bias is provided to a substrate support in the chamber, or
   cycles in which a condition of a gas supplied into the chamber is changed.

### E3

The anomaly detection method according to E2, wherein
the value of the at least one state includes at least one of:
   a voltage value on a feed line for the source radio-frequency power,
   a current value on the feed line for the source radio-frequency power,
   a phase difference between a voltage and a current on the feed line for the source radio-frequency power,
   a voltage value on a feed line for the electrical bias,
   a current value on the feed line for the electrical bias,
   a phase difference between a voltage and a current on the feed line for the electrical bias,
   a power level of a traveling wave of the source radio-frequency power,
   a degree of reflection of the source radio-frequency power from a load,
   a power level of a traveling wave of the electrical bias,
   a degree of reflection of the electrical bias from a load,
   a voltage value of a lower electrode or an electrostatic chuck in the substrate support,
   a clamping voltage value of the electrostatic chuck,
   a clamping current value of the electrostatic chuck,
   an emission intensity in the chamber,
   an electron density in the chamber,
   a voltage value of an upper electrode above the substrate support to receive a direct current voltage, or
   a current value of the upper electrode to receive the direct current voltage.

### E4

The anomaly detection method according to any one of E1 to E3, wherein
the reference value used in the detecting is an average of values of the at least one state at the corresponding phases in a plurality of preceding cycles in the series.

### E5

The anomaly detection method according to any one of E1 to E4, wherein
the detecting further includes providing an alert in the plasma processing device when an absolute value of a difference between the value of the at least one state at each phase in each of the cycles in the series and the reference value is greater than a first threshold.

### E6

The anomaly detection method according to E5, wherein
the first threshold is Q₁ times a standard deviation of values of the at least one state at the corresponding phases in a plurality of preceding cycles in the series, where Q₁ is a positive value.

### E7

The anomaly detection method according to E5, wherein
the detecting further includes stopping an operation of the plasma processing device when the absolute value of the difference between the value of the at least one state at each phase in each of the cycles in the series and the reference value is greater than a second threshold, and
the second threshold is greater than the first threshold.

### E8

The anomaly detection method according to E7, wherein
the first threshold is Q₁ times a standard deviation of values of the at least one state at the corresponding phases in a plurality of preceding cycles in the series, and
the second threshold is Q₂ times the standard deviation, where Q₁ and Q₂ are positive values, and Q₂ is greater than Q₁.

### E9

A plasma processing device, comprising:
a chamber;
a substrate support in the chamber; and
a controller configured to change at least one processing condition of plasma processing in the chamber in cycles, the controller being configured to detect an anomaly in the plasma by comparing, in a series of the cycles being repeated and in which the at least one processing condition is changed, a value of at least one state of plasma in the chamber at each phase in each of the cycles in the series with a reference value which is based on values of the at least one state at corresponding phases in one or more preceding cycles in the series.

### E10

The plasma processing device according to E9, further comprising:
a radio-frequency power supply configured to generate source radio-frequency power to generate the plasma in the chamber;
a bias power supply configured to provide an electrical bias to the substrate support; and
a gas supply configured to supply a gas into the chamber,
wherein the cycles are
   cycles in which a pulse of the source radio-frequency power is provided from the radio-frequency power supply,
   cycles in which a pulse of the electrical bias is provided to the substrate support from the bias power supply, or
   cycles in which a condition of a gas supplied into the chamber is changed.

### E11

The plasma processing device according to E10, wherein
the value of the at least one state includes at least one of:
   a voltage value on a feed line for the source radio-frequency power,
   a current value on the feed line for the source radio-frequency power,
   a phase difference between a voltage and a current on the feed line for the source radio-frequency power,
   a voltage value on a feed line for the electrical bias,
   a current value on the feed line for the electrical bias,
   a phase difference between a voltage and a current on the feed line for the electrical bias,
   a power level of a traveling wave of the source radio-frequency power,
   a degree of reflection of the source radio-frequency power from a load,
   a power level of a traveling wave of the electrical bias,
   a degree of reflection of the electrical bias from a load,
   a voltage value of a lower electrode or an electrostatic chuck in the substrate support,
   a clamping voltage value of the electrostatic chuck,
   a clamping current value of the electrostatic chuck,
   an emission intensity in the chamber,
   an electron density in the chamber,
   a voltage value of an upper electrode above the substrate support to receive a direct current voltage, or
   a current value of the upper electrode to receive the direct current voltage.

### E12

The plasma processing device according to any one of E9 to E11, wherein
the reference value is an average of values of the at least one state at the corresponding phases in two or more preceding cycles in the series.

### E13

The plasma processing device according to any one of E9 to E12, wherein
the controller is configured to provide an alert when an absolute value of a difference between the value of the at least one state at each phase in each of the cycles in the series and the reference value is greater than a first threshold.

### E14

The plasma processing device according to E13, wherein
the first threshold is Q₁ times a standard deviation of values of the at least one state at the corresponding phases in a plurality of preceding cycles in the series, where Q₁ is a positive value.

### E15

The plasma processing device according to E13, wherein
the controller is configured to stop an operation of the plasma processing device when the absolute value of the difference between the value of the at least one state at each phase in each of the cycles in the series and the reference value is greater than a second threshold, and
the second threshold is greater than the first threshold.

### E16

The plasma processing device according to E15, wherein
the first threshold is Q₁ times a standard deviation of values of the at least one state at the corresponding phases in a plurality of preceding cycles in the series, and
the second threshold is Q₂ times the standard deviation, where Q₁ and Q₂ are positive values, and Q₂ is greater than Q₁.

Various exemplary embodiments according to the disclosure have been described by way of example, and various changes may be made without departing from the scope and spirit of the disclosure. The exemplary embodiments described above are thus not restrictive, and the true scope and spirit of the disclosure are defined by the appended claims.

What is claimed is:

1. An anomaly detection method, comprising:
changing at least one processing condition of plasma processing in cycles, the plasma processing being performed in a chamber in a plasma processing device;
obtaining, in a series of the cycles being repeated and in which the at least one processing condition is changed, a value of at least one state of plasma in the chamber at each phase in each of the cycles in the series; and
detecting an anomaly in the plasma by comparing the value of the at least one state at each phase in each of the cycles in the series with a reference value obtained based on values of the at least one state at corresponding phases in one or more preceding cycles in the series.

2. The anomaly detection method according to claim 1, wherein
the cycles are
cycles in which a pulse of a source radio-frequency power is provided to generate the plasma in the chamber,
cycles in which a pulse of an electrical bias is provided to a substrate support in the chamber, or
cycles in which a condition of a gas supplied into the chamber is changed.

3. The anomaly detection method according to claim 2, wherein
the value of the at least one state includes at least one of:
a voltage value on a feed line for the source radio-frequency power,
a current value on the feed line for the source radio-frequency power,
a phase difference between a voltage and a current on the feed line for the source radio-frequency power,
a voltage value on a feed line for the electrical bias,
a current value on the feed line for the electrical bias,
a phase difference between a voltage and a current on the feed line for the electrical bias,
a power level of a traveling wave of the source radio-frequency power,
a degree of reflection of the source radio-frequency power from a load,
a power level of a traveling wave of the electrical bias,
a degree of reflection of the electrical bias from a load,
a voltage value of a lower electrode or an electrostatic chuck in the substrate support,
a clamping voltage value of the electrostatic chuck,
a clamping current value of the electrostatic chuck,
an emission intensity in the chamber,
an electron density in the chamber,
a voltage value of an upper electrode above the substrate support to receive a direct current voltage, or
a current value of the upper electrode to receive the direct current voltage.

4. The anomaly detection method according to claim 1, wherein
the reference value used in the detecting is an average of values of the at least one state at the corresponding phases in a plurality of preceding cycles in the series.

5. The anomaly detection method according to claim 1, wherein
the detecting further includes providing an alert in the plasma processing device when an absolute value of a difference between the value of the at least one state at each phase in each of the cycles in the series and the reference value is greater than a first threshold.

6. The anomaly detection method according to claim 5, wherein
the first threshold is Q₁ times a standard deviation of values of the at least one state at the corresponding phases in a plurality of preceding cycles in the series, where Q₁ is a positive value.

7. The anomaly detection method according to claim 5, wherein
the detecting further includes stopping an operation of the plasma processing device when the absolute value of the difference between the value of the at least one state at each phase in each of the cycles in the series and the reference value is greater than a second threshold, and
the second threshold is greater than the first threshold.

8. The anomaly detection method according to claim 7, wherein
the first threshold is Q₁ times a standard deviation of values of the at least one state at the corresponding phases in a plurality of preceding cycles in the series, and
the second threshold is Q₂ times the standard deviation, where Q₁ and Q₂ are positive values, and Q₂ is greater than Q₁.

9. A plasma processing device, comprising:
a chamber;
a substrate support in the chamber; and
a controller configured to change at least one processing condition of plasma processing in the chamber in cycles, the controller being configured to detect an anomaly in the plasma by comparing, in a series of the cycles being repeated and in which the at least one processing condition is changed, a value of at least one state of plasma in the chamber at each phase in each of the cycles in the series with a reference value which is based on values of the at least one state at corresponding phases in one or more preceding cycles in the series.

10. The plasma processing device according to claim 9, further comprising:
a radio-frequency power supply configured to generate source radio-frequency power to generate the plasma in the chamber;
a bias power supply configured to provide an electrical bias to the substrate support; and
a gas supply configured to supply a gas into the chamber,
wherein the cycles are
cycles in which a pulse of the source radio-frequency power is provided from the radio-frequency power supply,
cycles in which a pulse of the electrical bias is provided to the substrate support from the bias power supply, or
cycles in which a condition of a gas supplied into the chamber is changed.

11. The plasma processing device according to claim 10, wherein
the value of the at least one state includes at least one of:
a voltage value on a feed line for the source radio-frequency power,
a current value on the feed line for the source radio-frequency power,
a phase difference between a voltage and a current on the feed line for the source radio-frequency power,
a voltage value on a feed line for the electrical bias,
a current value on the feed line for the electrical bias,
a phase difference between a voltage and a current on the feed line for the electrical bias,
a power level of a traveling wave of the source radio-frequency power,
a degree of reflection of the source radio-frequency power from a load,
a power level of a traveling wave of the electrical bias,
a degree of reflection of the electrical bias from a load,
a voltage value of a lower electrode or an electrostatic chuck in the substrate support,
a clamping voltage value of the electrostatic chuck,
a clamping current value of the electrostatic chuck,
an emission intensity in the chamber,
an electron density in the chamber,
a voltage value of an upper electrode above the substrate support to receive a direct current voltage, or
a current value of the upper electrode to receive the direct current voltage.

12. The plasma processing device according to claim 9, wherein
the reference value is an average of values of the at least one state at the corresponding phases in two or more preceding cycles in the series.

13. The plasma processing device according to claim 9, wherein
the controller is configured to provide an alert when an absolute value of a difference between the value of the at least one state at each phase in each of the cycles in the series and the reference value is greater than a first threshold.

14. The plasma processing device according to claim 13, wherein
the first threshold is Q₁ times a standard deviation of values of the at least one state at the corresponding phases in a plurality of preceding cycles in the series, where Q₁ is a positive value.

15. The plasma processing device according to claim 13, wherein
the controller is configured to stop an operation of the plasma processing device when the absolute value of the difference between the value of the at least one state at each phase in each of the cycles in the series and the reference value is greater than a second threshold, and
the second threshold is greater than the first threshold.

16. The plasma processing device according to claim 15, wherein
the first threshold is Q₁ times a standard deviation of values of the at least one state at the corresponding phases in a plurality of preceding cycles in the series, and
the second threshold is Q₂ times the standard deviation, where Q₁ and Q₂ are positive values, and Q₂ is greater than Q₁.
